(19) United States
(12) Patent Application Publication
(10) Pub. No.: US 2015/0113826 A1
(43) Pub. Date: Apr. 30, 2015

(54) SUBSTRATE PLACING TABLE AND SUBSTRATE PROCESSING APPARATUS

(71) Applicant: TOKYO ELECTRON LIMITED, Tokyo (JP)

(72) Inventors: Masaya Odagiri, Nirasaki-shi (JP); Jin Fujihara, Nirasaki-shi (JP)

(21) Appl. No.: 14/407,310

(22) PCT Filed: May 21, 2013
(86) PCT No.: PCT/JP2013/064135

§ 371 Date: Dec. 11, 2014

(30) Foreign Application Priority Data
Jun. 13, 2012 (JP) 2012-133702

(51) Int. Cl. H01L 21/687; H01L 21/67

(52) U.S. Cl. CPC H01L 21/68785; H01L 21/68771; H01L 21/67017
USPC 34/443; 269/289 R

(57) ABSTRACT

A peripheral member having the temperature thereof controlled to a first temperature; a center member, which is not in contact with the peripheral member and has the temperature thereof controlled to a second temperature; a periphery placing member having the peripheral portion of the wafer placed thereon; and a center placing member having the center portion of the wafer W placed thereon. The periphery placing member and the center placing member respectively have shapes different from those of the peripheral member and the center member so as to correspond to processing distribution. A portion of the periphery placing member is heat-insulated by having a gap formed between the portion and the center member. A portion of the center placing member is heat-insulated by having a gap formed between the portion and the peripheral member.

### TECHNICAL FIELD

The present disclosure relates to a substrate placing table for use in a substrate processing apparatus which processes a substrate, and a substrate processing apparatus provided with the substrate placing table.

### BACKGROUND

In the manufacture of a semiconductor device, a desired device is manufactured by repeatedly performing various kinds of processes such as a film-forming process and an etching process with respect to a semiconductor wafer (hereinafter simply referred to as a “wafer”) as a substrate.

In the related art, for the purpose of securing processing uniformity when processing a substrate, there is proposed a technology in which two coolant flow paths are concentrically installed within a substrate placing table configured to place the substrate thereon. The temperature of a coolant flowing through an outer flow path and the temperature of a coolant flowing through an inner flow path are made different from each other. Thus, the temperature of a substrate periphery portion and the temperature of a substrate center portion are independently controlled. Accordingly, the processing uniformity is obtained by correcting a processing distribution (see, e.g., Patent Document 1).

However, in the aforementioned technology, two temperature-adjusting-medium flow paths, through which temperature adjusting media (coolants) having mutually different temperatures can flow, are disposed adjacent to each other within one substrate placing table. For that reason, the temperatures of the temperature adjusting media flowing through the two temperature-adjusting-medium flow paths may affect each other. Thus, it cannot be said that the independence of temperature controllability in central and peripheral portions of the substrate is sufficient. It is therefore difficult to accurately control the temperatures of the central and peripheral portions of the substrate placed on the substrate placing table. This makes it impossible to sufficiently correct the processing distribution.

In order to solve this problem, there is proposed a substrate placing table including a peripheral placing member which supports a peripheral portion of a substrate and controls the temperature thereof and a central placing member which supports a central portion of a substrate and controls the temperature thereof. A gap is formed between the peripheral placing member and the central placing member such that they should not make contact with each other (see Patent Document 2).

### PRIOR ART DOCUMENTS

Patent Documents

Patent Document 1: Japanese laid-open publication No. H09-017770

Patent Document 2: Japanese laid-open publication No. 2012-015285

In the technology of Patent Document 2, as a typical embodiment, the peripheral placing member and the central placing member are concentrically installed. However, if the processing distribution is not concentric, for example, if the processing distribution is an elliptical distribution or an eccentric distribution, it is difficult to adjust the processing distribution so as to become uniform.

In this case, it is conceivable to design the peripheral placing member and the central placing member in conformity with the processing distribution. In that case, however, it is difficult to adapt the peripheral placing member and the central placing member to other processes. It can be considered to prepare dedicated placing tables on a process-by-process basis. In that case, cost becomes enormous.

### SUMMARY

It is therefore an object of the present disclosure to provide a substrate placing table capable of realizing optimal temperature distribution control depending on processes and a substrate processing apparatus provided with the substrate placing table.

Another object of the present disclosure is to provide a substrate placing table capable of realizing optimal temperature distribution control at a low cost on a process-by-process basis with respect to a plurality of processes and a substrate processing apparatus provided with the substrate placing table.

According to one embodiment of the present disclosure, there is provided a substrate placing table for supporting a workpiece substrate in a substrate processing apparatus which performs a specified process with respect to the workpiece substrate, including: a peripheral member installed in a corresponding relationship with a peripheral portion of the workpiece substrate and temperature-controlled to a first temperature; a central member installed in a corresponding relationship with a central portion of the workpiece substrate, the central member insulated from the peripheral member and temperature-controlled to a second temperature differing from the first temperature; a peripheral placing member installed above the peripheral member so as to make contact with the peripheral member and configured to support the peripheral portion of the workpiece substrate; and a central placing member installed above the central member so as to make contact with the central member and so as to be insulated from the peripheral placing member, the central placing member configured to support the central portion of the workpiece substrate, wherein the peripheral placing member and the central placing member are formed into shapes differing from the shapes of the peripheral member and the central member, respectively, so as to correspond to a processing distribution, the peripheral placing member is installed such that a portion of the peripheral placing member corresponding to the peripheral member makes contact with the peripheral member and a portion of the peripheral placing member protruding toward the central member is insulated from the central member, and the central placing member is installed such that a portion of the central placing member corresponding to the central member makes contact with the central member and a portion of the central placing member protruding toward the peripheral member is insulated from the peripheral member.

Further, according to one embodiment of the present disclosure, the central member is kept out of contact with the peripheral member and insulated from the peripheral member by a gap formed between the central member and the peripheral member; the central placing member is kept out of contact with the peripheral placing member and insulated from the peripheral placing member by a gap formed between the central placing member and the peripheral placing member; the portion of the peripheral placing member protruding toward the central member is insulated from the central member by a gap formed between the portion of the peripheral placing member and the central member; and the portion of the central placing member protruding toward the peripheral member is insulated from the peripheral member by a gap formed between the portion of the central placing member and the peripheral member.

Still further, according to one embodiment of the present disclosure, the peripheral member includes an annular peripheral portion corresponding to the peripheral portion of the workpiece substrate; the central member includes a disc-shaped central portion corresponding to the central portion of workpiece substrate; the peripheral placing member includes a peripheral placing portion installed above the peripheral portion of the peripheral member; and the central placing member includes a central placing portion installed above the central portion of the central member.

Further, at least two workpiece substrates are placed on the substrate placing table; the peripheral member includes at least two peripheral portions corresponding to peripheral portions of the respective workpiece substrates and a peripheral portion connecting portion configured to interconnect the peripheral portions; the central member includes at least two central portions corresponding to central portions of the respective workpiece substrates and a central portion connecting portion configured to interconnect the central portions; the peripheral placing member includes at least two peripheral placing portions installed above the peripheral portions; and the central placing member includes at least two central placing portions installed above the central portions, wherein at least two said peripheral portions have an annular shape and at least two said central portions have a disc shape.

Further, according to one embodiment of the present disclosure, plural sets of the peripheral placing member and the central placing member are prepared in a corresponding relationship with a plurality of processes, and a set of the peripheral placing member and the central placing member suitable for a process to be implemented is selected and mounted.

Still further, according to one embodiment of the present disclosure, the peripheral member and the central member include temperature-adjusting-medium flow paths installed therein, and further including: temperature-adjusting-medium circulating mechanisms configured to independently supply a temperature adjusting medium to the temperature-adjusting-medium flow paths. Also, projections configured to support the workpiece substrate are formed on a front surface of the central placing member.

According to another embodiment of the present disclosure, there is provided a substrate processing apparatus for implementing a specified process with respect to a workpiece substrate under a vacuum atmosphere, including: a chamber configured to accommodate the workpiece substrate; an exhaust mechanism configured to vacuum-exhaust the interior of the chamber; a process gas introduction mechanism configured to introduce a process gas into the chamber; and a substrate placing table configured to support the workpiece substrate within the chamber, wherein the substrate placing table includes: a peripheral member installed in a corresponding relationship with a peripheral portion of the workpiece substrate and temperature-controlled to a first temperature; a central member installed in a corresponding relationship with a central portion of the workpiece substrate, the central member insulated from the peripheral member and temperature-controlled to a second temperature differing from the first temperature; a peripheral placing member installed above the peripheral member so as to make contact with the peripheral member and configured to support the peripheral portion of the workpiece substrate; and a central placing member installed above the central member so as to make contact with the central member and so as to be insulated from the peripheral placing member, the central placing member configured to support the central portion of the workpiece substrate, wherein the peripheral placing member and the central placing member are formed into shapes differing from the shapes of the peripheral member and the central member, respectively, so as to correspond to a processing distribution, the peripheral placing member is installed such that a portion of the peripheral placing member corresponding to the peripheral member makes contact with the peripheral member and a portion of the peripheral placing member protruding toward the central member is insulated from the central member, and the central placing member is installed such that a portion of the central placing member corresponding to the central member makes contact with the central member and a portion of the central placing member protruding toward the peripheral member is insulated from the peripheral member.

### BRIEF DESCRIPTION OF THE DRAWINGS

FIG. 1 is a schematic configuration view illustrating a processing system provided with a COR processing apparatus configured to perform a COR process, which is a substrate processing apparatus according to a first embodiment of the present disclosure.

FIG. 2 is a sectional view illustrating the schematic configuration of a PHT processing apparatus mounted to the processing system shown in FIG. 1.

FIG. 3 is a sectional view illustrating the schematic configuration of a COR processing apparatus as a substrate processing apparatus according to a first embodiment of the present disclosure, which is mounted to the processing system shown in FIG. 1.

FIG. 4 is an exploded perspective view illustrating a substrate placing table installed in the COR processing apparatus shown in FIG. 3.

FIG. 5 is a plan view illustrating the substrate placing table installed in the COR processing apparatus shown in FIG. 3.

FIG. 6 is a sectional view taken along line A-A in FIG. 5, illustrating the substrate placing table installed in the COR processing apparatus shown in FIG. 3.

FIG. 7 is a sectional view illustrating the schematic configuration of a COR processing apparatus as a substrate processing apparatus according to a second embodiment of the present disclosure.

FIG. 8 is an exploded perspective view illustrating a substrate placing table installed in the COR processing apparatus shown in FIG. 7.

FIG. 9 is a plan view illustrating the substrate placing table installed in the COR processing apparatus shown in FIG. 7.

FIG. 10 is a sectional view taken along line B-B in FIG. 9, illustrating the substrate placing table installed in the COR processing apparatus shown in FIG. 7.

### DETAILED DESCRIPTION

Embodiments of the present disclosure will now be described in detail with reference to the accompanying drawings.

### First Embodiment

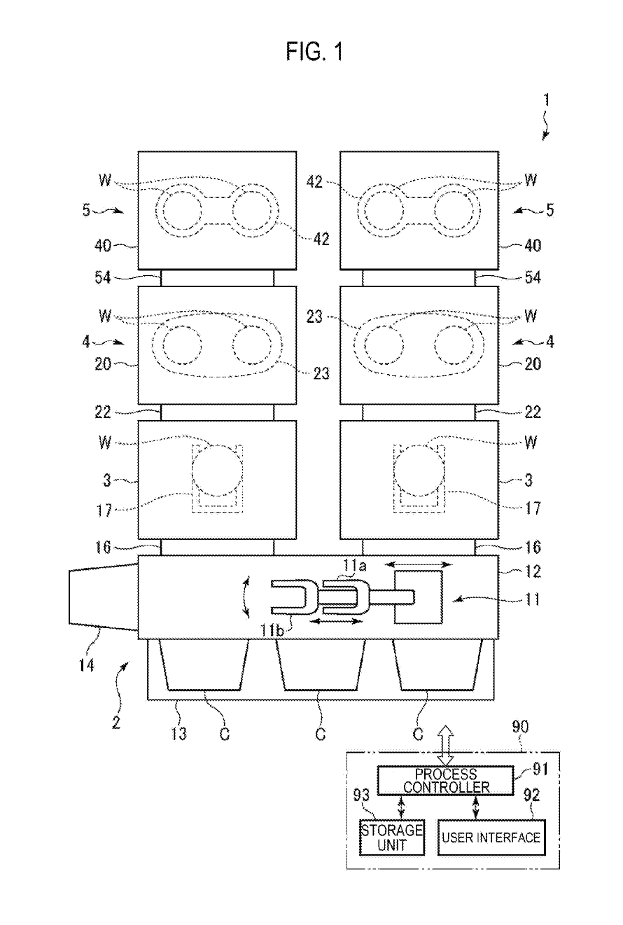

FIG. 1 is a schematic configuration view illustrating a processing system provided with a COR processing apparatus for performing a COR (Chemical Oxide Removal) process, which is a substrate processing apparatus according to a first embodiment of the present disclosure. The processing system 1 includes a carry-in/carry-out part 2 configured to carry in and out a semiconductor wafer (hereinafter simply referred to as a “wafer”) W as a workpiece substrate, two load lock chambers (L/L) 3 installed adjacent to the carry-in/carry-out part 2, PHT processing apparatuses 4 installed adjacent to the respective load lock chambers 3 and configured to perform a PHT (Post Heat Treatment) process with respect to a wafer W, and a COR processing apparatuses 5 installed adjacent to the respective PHT processing apparatuses 4 and configured to perform a COR process with respect to a wafer W. The load lock chambers 3, the PHT processing apparatuses 4 and the COR processing apparatuses 5 are arranged side by side along a straight line in the above-mentioned order. The PHT processing apparatuses 4 and the COR processing apparatuses 5 are configured to process two wafers W at one time.

The carry-in/carry-out part 2 includes a transfer chamber (L/M) 12 within which a first wafer transfer mechanism 11 for transferring a wafer W is installed. The first wafer transfer mechanism 11 includes two transfer arms 11a and 11b configured to substantially horizontally hold a wafer W. A mounting stand 13 is installed at one longitudinal side portion of the transfer chamber 12. Then, for example, three carriers C capable of accommodating a plurality of wafers W can be connected to the mounting stand 13. In addition, an orientor 14 configured to rotate a wafer W, optically calculating an eccentricity of the wafer W and aligning the position of the wafer W is installed adjacent to the transfer chamber 12.

In the carry-in/carry-out part 2, wafers W are held by the transfer arms 11a and 11b. The wafers W are linearly moved within a substantially horizontal plane and moved up and down by the first wafer transfer mechanism 11. Thus, the wafers W are transferred to a desired position. The wafers W are carried into and out of the carriers C on the mounting stand 13, the orientor 14 and the load lock chambers 3, respectively, as the transfer arms 11a and 11b are moved back and forth.

The respective load lock chambers 3 are connected to the transfer chamber 12 with respective gate valves 16 interposed between the load lock chambers 3 and the transfer chamber 12. A second wafer transfer mechanism 17 configured to transfer a wafer W is installed within each of the load lock chambers 3. The load lock chambers 3 are configured such that they can be vacuum-drawn to a predetermined vacuum degree.

The second wafer transfer mechanism 17 includes an articulated arm structure and a pick configured to substantially horizontally hold a wafer W. In the second wafer transfer mechanism 17, when the articulated arm is retracted, the pick is positioned within each of the load lock chambers 3. If the articulated arm is extended, the pick can reach the PHT processing apparatus 4. If the articulated arm is further extended, the pick can reach the COR processing apparatus 5. Thus, the second wafer transfer mechanism 17 can transfer a wafer W among the load lock chamber 3, the PHT processing apparatus 4 and the COR processing apparatus 5.

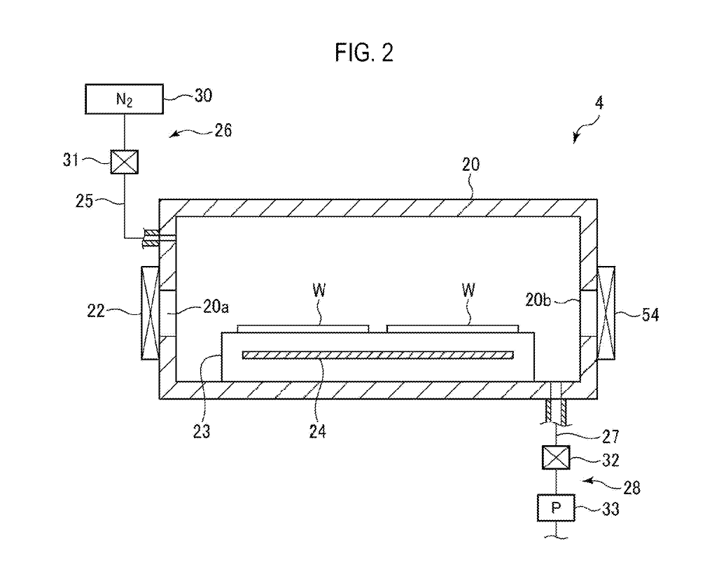

The PHT processing apparatus 4 is configured as shown by a sectional view in FIG. 2. That is, the PHT processing apparatus 4 includes a chamber 20 capable of being vacuum-drawn and a substrate placing table 23 provided with the chamber 20 which is configured to horizontally support two wafers W as workpiece substrates. A heater 24 is embedded in the substrate placing table 23. The wafers W subjected to a COR process are heated by the heater 24. Then, a PHT process for vaporizing (sublimating) a below-mentioned reaction product generated by a COR process is performed. A carry-in/carry-out gate 20a through which a wafer W is transferred between the chamber 20 and the load lock chamber 3 is installed at the load lock chamber 3 of the chamber 20. The carry-in/carry-out gate 20a can be opened and closed by a gate valve 22. A carry-in/carry-out gate 20b through which a wafer W is transferred between the chamber 20 and the COR processing apparatus 5 is installed at the COR processing apparatus 5 of the chamber 20. The carry-in/carry-out gate 20b can be opened and closed by a gate valve 54. The PHT processing apparatus 4 includes a gas supply mechanism 26 provided with a gas supply path 25 and configured to supply an inert gas such as, e.g., a nitrogen gas (N₂) or the like into the chamber 20 and an exhaust mechanism 28 provided with an exhaust pipe 27 and configured to evacuate the interior of the chamber 20. The gas supply path 25 is connected to a nitrogen gas supply source 30. A flow rate control valve 31 capable of performing a flow path opening/closing operation and controlling a supply flow rate of a nitrogen gas is installed at the gas supply path 25. An opening/closing valve 32 and a vacuum pump 33 are installed at the exhaust pipe 27 of the exhaust mechanism 28. In FIG. 2, for convenience, two wafers W are placed on the substrate placing table 23 along a transfer direction of the wafers W. However, in reality, as shown in FIG. 1, the wafers W are disposed along a direction perpendicular to the transfer direction of the wafers W.

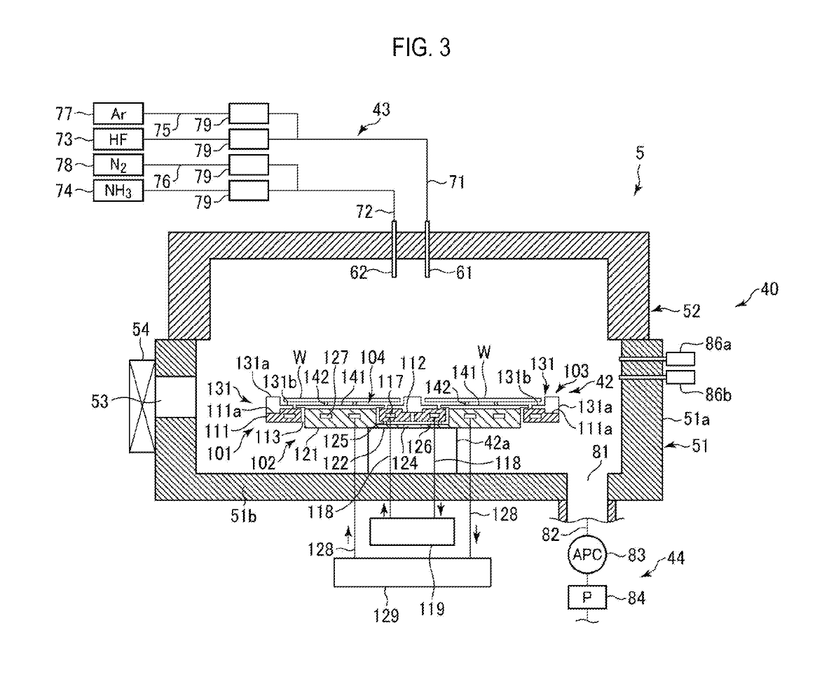

The COR processing apparatus 5 is configured as shown by a sectional view in FIG. 3. That is, as shown in FIG. 3, the COR processing apparatus 5 includes a chamber 40 having a tightly sealed structure. A substrate placing table 42 configured to horizontally support two wafers W as workpiece substrates is installed within the chamber 40. The COR processing apparatus 5 further includes a gas supply mechanism 43 configured to supply an HF gas and an NH₃ gas into the chamber 40 and an exhaust mechanism 44 configured to exhaust the interior of the chamber 40.

The chamber 40 is provided with a chamber body 51 and a cover portion 52. The chamber body 51 includes a substantially cylindrical sidewall portion 51 a and a bottom portion 51b. The top portion of the chamber body 51 is formed into an opening which is closed by the cover portion 52. The sidewall portion 51 a and the cover portion 52 are sealed by a seal member (not shown) so as to secure air-tightness of the interior of the chamber 40. A first gas introduction nozzle 61 and a second gas introduction nozzle 62 are inserted into the chamber 40 from above a ceiling wall of the cover portion 52.

A carry-in/carry-out gate 53 through which wafers W are carried into and out of the chamber 20 of the PHT processing apparatus 4 is installed at the sidewall portion 51a. The carry-in/carry-out gate 53 can be opened and closed by a gate valve 54.

The gas supply mechanism 43 includes a first gas supply pipe 71 and a second gas supply pipe 72 which are connected to the first gas introduction nozzle 61 and the second gas introduction nozzle 62, respectively. The gas supply mechanism 43 further includes an HF gas supply source 73 and an NH₃ gas supply source 74 which are connected to the first gas supply pipe 71 and the second gas supply pipe 72, respectively. A third gas supply pipe 75 is connected to the first gas supply pipe 71. A fourth gas supply pipe 76 is connected to the second gas supply pipe 72. An Ar gas supply source 77 and a N₂ gas supply source 78 are connected to the third gas supply pipe 75 and the fourth gas supply pipe 76, respectively. Flow rate controllers 79 configured to perform a flow path opening/closing operation and a flow rate control operation are installed at the first to fourth gas supply pipes 71, 72, 75 and 76. Each of the flow rate controllers 79 is provided with, e.g., an opening/closing valve and a mass flow controller.

An HF gas and an Ar gas are injected into the chamber 40 through the first gas supply pipe 71 and the first gas introduction nozzle 61. An NH₃ gas and an N₂ gas are injected into the chamber 40 through the second gas supply pipe 72 and the second gas introduction nozzle 62. Alternatively, the gases may be injected in a shower pattern using a shower plate.

Among the gases, the HF gas and the NH₃ gas are reaction gases and are initially mixed within the chamber 40. The Ar gas and the N₂ gas are dilution gases. The HF gas and the NH₃ gas as reaction gases and the Ar gas and the N₂ gas as dilution gases are introduced into the chamber 40 at predetermined flow rates. While the interior of the chamber 40 is maintained at a predetermined pressure, the HF gas and the NH₃ gas react with an oxide film (SiO₂) formed on the front surface of the wafer W. Thus, this generates ammonium fluorosilicate (AFS) as a reaction product.

As the dilution gas, it may be possible to use only the Ar gas or only the N₂ gas. It may also be possible to use other inert gases, or two or more of the Ar gas, the N₂ gas and other inert gases.

The exhaust mechanism 44 includes an exhaust pipe 82 connected to an exhaust hole 81 formed at the bottom portion 51b of the chamber 40. The exhaust mechanism 44 further includes an automatic pressure control valve (APC) 83 installed at the exhaust pipe 82 and configured to control the internal pressure of the chamber 40, and a vacuum pump 84 configured to exhaust the interior of the chamber 40.

Two capacitance manometers 86a and 86b as manometers for measuring the internal pressure of the chamber 40 are installed in the chamber 40 from the sidewall of the chamber 40. The capacitance manometer 86a is used for measuring a high pressure, and the capacitance manometer 86b is used for measuring a low pressure.

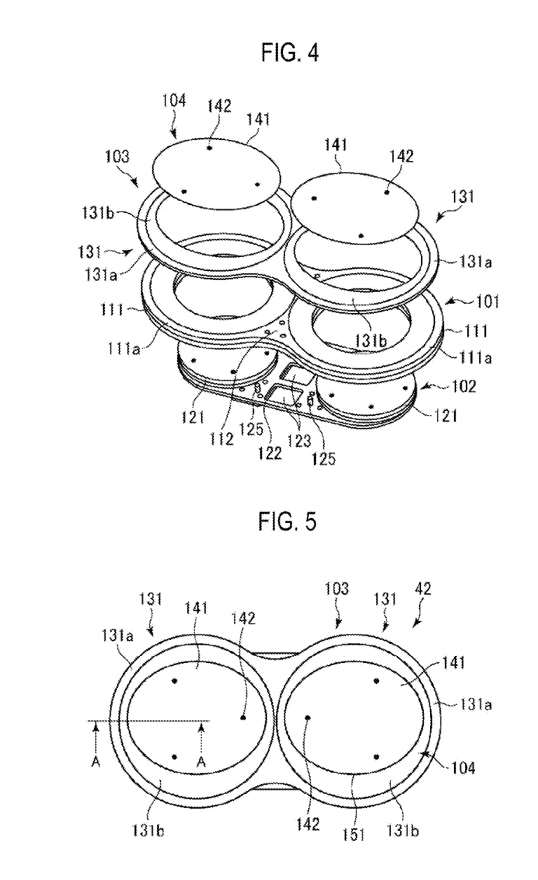

The substrate placing table 42 is configured to support two wafers W as substrates and is supported by a support base 42a. As shown by an exploded perspective view in FIG. 4, the substrate placing table 42 includes a peripheral member 101 corresponding to the peripheral portions of two wafers W, a central member 102 corresponding to the central portions of two wafers W, a peripheral placing member 103 installed above the peripheral member 101 and configured to support the peripheral portions of two wafers W, and a central placing member 104 installed above the central member 102 and configured to support the central portions of two wafers W. The peripheral member 101, the central member 102, the peripheral placing member 103 and the central placing member 104 overlap with one another.

The peripheral member 101 includes two ring-shaped peripheral portions 111 corresponding to the peripheral portions of the respective wafers W, and a peripheral portion connecting portion 112 configured to interconnect two peripheral portions 111 being arranged side by side horizontally. The central member 102 includes two disc-shaped central portions 121 corresponding to the central portions of the respective wafers W, and a central portion connecting portion 122 configured to interconnect two central portions 121 being arranged side by side horizontally. Two peripheral portions 111 and two central portions 121 correspond to each other. When the peripheral member 101 and the central member 102 overlap with each other, the disc-shaped central portions 121 are inserted into the ring-shaped peripheral portions 111 with a gap 113 left therebetween.

The central portion connecting portion 122 is directly supported by the support base 42a. A hole portion 123 (see FIG. 4) is formed at the central portion connecting portion 122. A protrusion portion 124 (see FIG. 3) corresponding to the hole portion 123 is formed on the top surface of the support base 42a. The central member 102 is positioned so as to have the central member 102 be supported by the support base 42a such that the protrusion portion 124 is inserted into the hole portion 123.

Spacer pins 125 are installed on the top surface of the central portion connecting portion 122. Therefore, when the peripheral member 101 is overlapped with the central member 102, a gap 126 is formed between the central portion connecting portion 122 of the central member 102 and the peripheral member 101.

Since the gaps 113 and 126 are formed in this way, the peripheral member 101 and the central member 102 are kept out of contact with each other. As the interior of the chamber 40 is vacuum-exhausted, the peripheral member 101 and the central member 102 are vacuum-insulated from each other.

A temperature-adjusting-medium flow path 117 is installed within the peripheral member 101. A temperature-adjusting-medium flow path 127 is installed within the central member 102. Temperature-adjusting-medium pipes 118 and 128 through which a temperature adjusting medium (cooling medium) such as, e.g., cooling water or the like, circulates are connected to the temperature-adjusting-medium flow paths 117 and 127, respectively. Temperature-adjusting-medium circulating mechanisms 119 and 129 configured to circulate a temperature adjusting medium adjusted to different temperatures are installed at the temperature-adjusting-medium pipes 118 and 128, respectively. The temperature adjusting medium is caused to flow into the temperature-adjusting-medium flow path 117 through the temperature-adjusting-medium pipe 118 by the temperature-adjusting-medium circulating mechanism 119. Thus, the temperature of the peripheral member 101 is controlled to a first temperature. In the meantime, the temperature adjusting medium is caused to flow into the temperature-adjusting-medium flow path 127 through the temperature-adjusting-medium pipe 128 by the temperature-adjusting-medium circulating mechanism 129. Thus, the temperature of the central member 102 is controlled to a second temperature differing from the temperature of the peripheral member 101.

The peripheral placing member 103 is configured by interconnecting two ring-shaped peripheral placing portions 131 corresponding to the peripheral portions of the respective wafers W. For example, the peripheral placing member 103 is detachably attached to the peripheral member 101. Each of the peripheral placing portions 131 includes a guide portion 131a which forms an outer edge, and a placing portion 131b which exists inside the guide portion 131a. The guide portion 131 a is formed to protrude upward and downward, such that the wafer W is guided by the upper portion of the guide portion 131a. A step portion 111a is formed at the outer edge of each of the peripheral portions 111. The lower portion of the guide portion 131a is fitted into the step portion 111a, thereby determining a position of the peripheral placing member 103. The peripheral portion of the wafer W is placed on the placing portion 131b.

The central placing member 104 includes two central placing portions 141 corresponding to the central portions of the respective wafers W. The central placing portions 141 have a specified positional relationship with the central portions 121 and are, for example, detachably attached to the central portions 121.

The peripheral placing portions 131 and the central placing portions 141 differ in shape from the peripheral portions 111 and the central portions 121 so as to correspond to a processing distribution. For example, as shown by a plan view in FIG. 5, the central placing portions 141 have an elliptical shape. The peripheral placing portions 131 have an annular shape corresponding to the central placing portions 141. Therefore, when the peripheral placing member 103 and the central placing member 104 are mounted in position, a gap 151 is formed between the peripheral placing portions 131 and the central placing portions 141. Thus, the peripheral placing portions 131 and the central placing portions 141 are kept out of contact with each other. The peripheral placing portions 131 and the central placing portions 141 are not limited to such a shape but may have different shapes depending on the processing distribution.

Three projections 142 are formed on the surface of each of the central placing portions 141. A wafer W is placed on the projections 142.

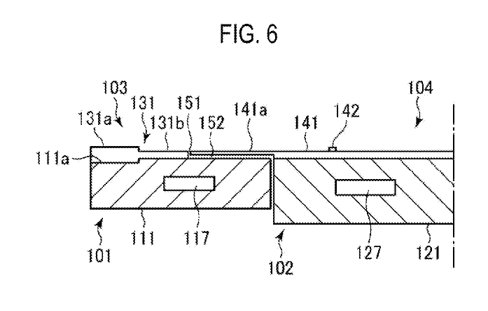

Since the central placing portions 141 differ in shape from the central portions 121, an overhang portion 141a protruding from each of the central portions 121 toward each of the peripheral portions 111 exists at each of the central placing portions 141 as shown in FIG. 6. A gap 152 is formed between the overhang portion 141a and each of the peripheral portions 111. Therefore, when the chamber 40 is vacuum-exhausted, the overhang portion 141a is vacuum-insulated from each of the peripheral portions 111. While not shown in the drawings, an overhang portion protruding toward each of the central portions 121 exists at each of the peripheral placing portions 131. A gap is formed between the overhang portion and each of the central portions 121. Therefore, the overhang portion is vacuum-insulated from each of the central portions 121. In the meantime, the regions of the peripheral placing portions 131 (the peripheral placing member 103) corresponding to the peripheral portions 111 (the peripheral member 101) make contact with the peripheral portions 111 (the peripheral member 101). The regions of the central placing portions 141 (the central placing member 104) corresponding to the central portions 121 (the central member 102) make contact with the central portions 121 (the central member 102).

As a result, the front surfaces of the central placing portions 141 including the overhang portions 141a are temperature-adjusted to a temperature substantially equal to the second temperature of the central member 102. This is due to the heat transfer from the central member 102 which is temperature-adjusted to the second temperature by the temperature adjusting medium. On the other hand, the front surfaces of the peripheral placing portions 131 including the overhang portions (not shown) are temperature-adjusted to a temperature substantially equal to the first temperature of the peripheral member 101. This is due to the heat transfer from the peripheral member 101 which is temperature-adjusted to the first temperature by the temperature adjusting medium.

A wafer W as a workpiece substrate is supported by the projections 142 as mentioned above. A small gap is formed between the wafer W and the front surfaces of the peripheral placing portions 131 and the central placing portions 141. Since the wafer W is placed with a small gap in this way, the heat of the peripheral placing portions 131 and the central placing portions 141 is transferred to the wafer W via a gas introduced into the chamber 40. Thus, the region of the wafer W corresponding to each of the peripheral placing portions 131 is temperature-adjusted to a temperature substantially equal to the first temperature. The region of the wafer W corresponding to each of the central placing portions 141 is temperature-adjusted to a temperature substantially equal to the second temperature.

While not shown in the drawings, three through-holes are formed in each of the central portions 121 of the central member 102 and in each of the central placing portions 141 of the central placing member 104. Lifter pins which can protrude and retract with respect to the front surface of each of the central placing portions 141 and which can support and move up and down a wafer W are installed within the above-mentioned through-holes. The lifter pins are moved up and down by a cylinder not shown. When delivering the wafer W, the lifter pins are moved upward such that the tips of the lifter pins are positioned higher than the front surface of each of the central placing portions 141. In FIG. 3, for convenience, two wafers W are placed on the substrate placing table 42 along a transfer direction of the wafers W. However, in reality, as shown in FIG. 1, the wafers W are disposed along a direction perpendicular to the transfer direction of the wafers W.

The respective members of the substrate placing table 42 are made of a metal superior in heat conductivity, e.g., aluminum. This makes it possible to efficiently transfer the heat of the temperature adjusting medium to the respective members and to accurately adjust the temperature of the wafer W as a substrate.

The material of other component parts such as the chamber 40 and the like which constitute the COR processing apparatus 5 may be aluminum. The aluminum material of which the chamber 40 and the like are made may be pure aluminum or aluminum whose surface is subjected to an anodizing treatment. Inasmuch as the surface of the aluminum material constituting the substrate placing table 42 is required to have wear resistance, an oxide film (Al₂O₃) having high wear resistance may be formed on the surface of the aluminum material by performing an anodizing treatment.

As shown in FIG. 1, the processing system 1 includes a control unit 90. The control unit 90 includes a process controller 91 provided with a microprocessor (computer) configured to control the respective component parts of the processing system 1. A user interface 92 including an input unit through which an operator performs a command input operation in order to manage the processing system 1 and a display which visually displays an operation situation of the processing system 1 is connected to the process controller 91. For the display, it is possible to use a display capable of inputting a command through an operation of a touch panel. Also a storage unit 93 is connected to the process controller 91. The storage unit 93 stores: a control program configured to realize, under the control of a controller, various kinds of processes implemented in the processing system 1, e.g., the supply of process gases in the COR processing apparatus 5, exhausting and temperature adjustment of the interior of the chamber 40, and the temperature adjustment of the substrate placing table 42; a process recipe as a control program configured to cause the respective component parts of the processing system 1 to perform a predetermined process depending on processing conditions; and various kinds of databases. Recipes are stored in a suitable storage medium (not shown) of the storage unit 93. If necessary, an arbitrary recipe is called out from the storage unit 93 and is executed by the process controller 91. Thus, a desired process is performed in the processing system 1 under the control of the process controller 91.

Next, description will be made on the processing operation implemented in the processing system 1. First, workpiece substrates, i.e., wafers W each having a silicon oxide film formed on the surface thereof, are accommodated within the carrier C. The carrier C is transferred to the processing system 1. In the processing system 1, the gate valve 16 at the atmosphere side is opened. In this state, one wafer W is transferred from the carrier C of the carry-in/carry-out part 2 to the load lock chamber 3 by one of the transfer arms 11a and 11b of the first wafer transfer mechanism 11. Then, the wafer W is delivered to the pick of the second wafer transfer mechanism 17 within the load lock chamber 3.

Thereafter, the gate valve 16 at the atmosphere side is closed and the interior of the load lock chamber 3 is vacuum-exhausted. Subsequently, the gate valves 22 and 54 are opened and the pick is extended to the COR processing apparatus 5 to place the wafer W onto the substrate placing table 42.

Then, the pick is returned to the load lock chamber 3 and the gate valve 54 is closed to tightly seal the interior of the chamber 40. In this state, the temperature adjusting media having different temperatures are caused to flow into the temperature-adjusting-medium flow paths 117 and 127 of the peripheral member 101 and the central member 102, by the temperature-adjusting-medium circulating mechanisms 119 and 129. Thus, this adjusts the temperature of the peripheral member 101 to a first temperature and the temperature of the central member 102 to a second temperature. Consequently, the temperature of the peripheral portion of the wafer W and the temperature of the central portion of the wafer W are independently controlled so as to perform a uniform processing.

In this state, an HF gas and an Ar gas are injected into the chamber 40 through the first gas supply pipe 71 and the first gas introduction nozzle 61 from the gas supply mechanism 43. An NH₃ gas and an N₂ gas are injected into the chamber 40 through the second gas supply pipe 72 and the second gas introduction nozzle 62. Only one of the Ar gas and the N₂ gas as dilution gases may be used.

In this way, the wafer W is COR-processed by the HF gas and the NH₃ gas injected into the chamber 40.

That is, a silicon oxide film formed on the front surface of the wafer W chemically reacts with molecules of the hydrogen fluoride gas and molecules of the ammonia gas. As a result, ammonium fluorosilicate (AFS), water and the like are produced as reaction products and are held on the front surface of the wafer W.

At this time, as described above, for the substrate placing table 42, the peripheral member 101 and the central member 102, which are temperature-adjusted to different temperatures, are installed with a gap left therebetween, so as not to make contact with each other. The independent temperature controllability is secured by vacuum-insulating the peripheral member 101 and the central member 102 from each other. In the related art, wafers W are placed on the peripheral member 101 and the central member 102 being provided with high temperature controllability. Thus, this assures uniformity of processing. However, in this configuration, if the processing distribution is not concentric, it is impossible to sufficiently achieve uniform processing distribution.

Accordingly, in the present embodiment, the peripheral placing member 103 and the central placing member 104 are mounted on the peripheral member 101 and the central member 102 in a contactless state, such that a gap is formed between the peripheral placing member 103 and the central placing member 104. The peripheral placing portions 131 and the central placing portions 141 are formed to have a shape differing from the shape of the peripheral portions 111 and the central portions 121 so as to correspond to the processing distribution. The overhang portion 141 a of each of the central placing portions 141 protruding toward each of the peripheral portions 111 is formed such that a gap 152 is formed between the overhang portion 141a and each of the peripheral portions 111. Thus, this provides vacuum insulation. The overhang portion (not shown) of each of the peripheral placing portions 131 protruding toward each of the central portions 121 is formed such that a gap is formed between the overhang portion and each of the central portions 121. Thus, this provides vacuum insulation. As a result, the front surfaces of the central placing portions 141 including the overhang portions 141a are temperature-adjusted to a temperature substantially equal to the second temperature of the central member 102. This is due to the heat transfer from the central member 102 which is temperature-adjusted to the second temperature by the temperature adjusting medium. On the other hand, the front surfaces of the peripheral placing portions 131 including the overhang portions (not shown) are temperature-adjusted to a temperature substantially equal to the first temperature of the peripheral member 101.

That is, the peripheral placing portions 131 (the peripheral placing member 103) and the central placing portions 141 (the central placing member 104) corresponding to the processing distribution and differing in shape from the peripheral portions 111 (the peripheral member 101) and the central portions 121 (the central member 102) are placed on the temperature-adjusted peripheral portions 111 (the peripheral member 101) and the temperature-adjusted central portions 121 (the central member 102). The temperature of the front surfaces of the peripheral placing portions 131 (the peripheral placing member 103) is set to become a temperature corresponding to the temperature of the peripheral portions 111 (the peripheral member 101). The temperature of the front surfaces of the central placing portions 141 (the central placing member 104) is set to become a temperature corresponding to the temperature of the central portions 121 (the central member 102). This makes it possible to adjust the temperature distribution of the wafer W in conformity with the processing distribution and to realize optimal temperature distribution control, which makes the processing distribution uniform depending on the processes.

If multiple sets of the peripheral placing member 103 and the central placing member 104 including the peripheral placing portions 131 and the central placing portions 141 having an optimal shape on a process-by-process basis are prepared, it is possible to select and mount a set of the peripheral placing member 103 and the central placing member 104 suitable for the process to be implemented. Consequently, the temperature distribution control capable of making the processing distribution uniform can be executed by merely replacing the peripheral placing member 103 and the central placing member 104. This makes it possible to realize optimal temperature distribution control for the respective processes in a cost-effective manner.

After the COR process is finished, the gate valves 22 and 54 are opened. The processed wafer W on the substrate placing table 42 is received by the pick of the second wafer transfer mechanism 17 and is placed on the substrate placing table 23 within the chamber 20 of the PHT processing apparatus 4. Then, the pick is moved back to the load lock chamber 3. The gate valves 22 and 54 are closed. While introducing an N₂ gas into the chamber 20, the wafer W placed on the substrate placing table 23 is heated by the heater 24. Thus, the reaction products generated by the COR process are heated, vaporized and removed.

In this way, by performing the PHT process after the COR process, it is possible to remove the silicon oxide film on the front surface of the wafer W under a dry atmosphere. Therefore, no watermark is generated. Since etching can be performed under a non-plasma condition, it is possible to perform a process with reduced damage. Etching does not occur after a predetermined time is elapsed from the COR process. Therefore, a reaction does not occur even if over-etching is applied. This eliminates the need for end point management.

### Second Embodiment

Next, description will be made on a COR processing apparatus according to a second embodiment of the present disclosure. In the first embodiment, description has been made by, as an example, a case where two wafers W as workpiece substrates are processed at one time. Needless to say, one wafer may be processed at one time. In the present embodiment, description will be made on an example where one wafer W as a workpiece substrate is processed at one time.

The processing system provided with the COR processing apparatus of the present embodiment remains the same as the processing system shown in FIG. 1 except that one wafer W is processed at one time. Therefore, description thereon will be omitted.

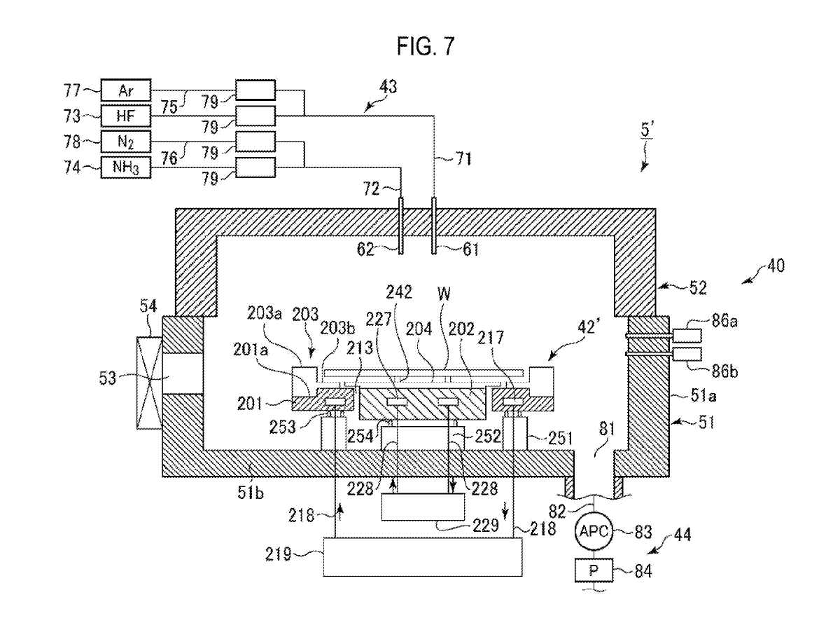

FIG. 7 is a sectional view showing the COR processing apparatus 5′ according to the present embodiment. In FIG. 7, the configurations other than the substrate placing table remain the same as those of the COR processing apparatus 5 shown in FIG. 1. Therefore, in FIG. 7, components identical with those shown in FIG. 1 will be designated by like reference symbols. The description thereon will be omitted.

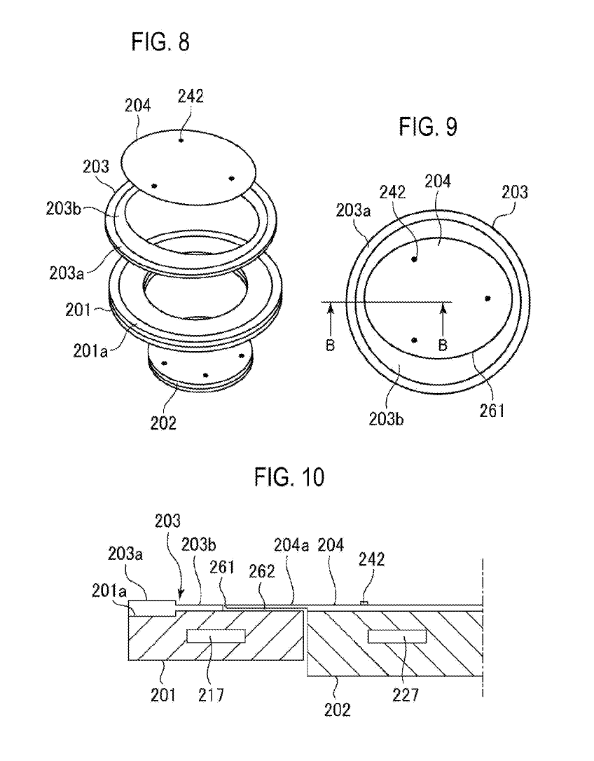

As shown by an exploded perspective view in FIG. 8, the substrate placing table 42′ includes a peripheral member 201 corresponding to the peripheral portion of the wafer W, a central member 202 corresponding to the central portion of the wafer W, a peripheral placing member 203 installed above the peripheral member 201 and configured to support the peripheral portion of the wafer W, and a central placing member 204 installed above the central member 202 and configured to support the central portion of the wafer W.

The peripheral member 201 has an annular shape. The central member 202 has a disc shape. The peripheral member 201 is installed so as to surround the central member 202. A gap 213 is formed between the peripheral member 201 and the central member 202. Thus, the peripheral member 201 and the central member 202 are kept out of contact with each other. As the interior of the chamber 40 is vacuum-exhausted, the peripheral member 201 and the central member 202 are vacuum-insulated from each other. The peripheral member 201 is supported by cylindrical peripheral support bases 251 installed at the bottom portion of the chamber 40 through support pins 253. The central member 202 is supported by a cylindrical columnar central support base 252 installed at the bottom portion of the chamber 40 through support pins 254. The peripheral support bases 251 and the peripheral member 201 are fixed to each other by a suitable means. In addition, the central support base 252 and the central member 202 are fixed to each other by a suitable means.

A temperature-adjusting-medium flow path 217 is installed within the peripheral member 201. A temperature-adjusting-medium flow path 227 is installed within the central member 202. Temperature-adjusting-medium pipes 218 and 228 through which a temperature adjusting medium (cooling medium) such as, e.g., cooling water or the like, circulates are connected to the temperature-adjusting-medium flow paths 217 and 227, respectively. Temperature-adjusting-medium circulating mechanisms 219 and 229 configured to circulate a temperature adjusting medium adjusted to different temperatures are installed at the temperature-adjusting-medium pipes 218 and 228, respectively. The temperature adjusting medium is caused to flow into the temperature-adjusting-medium flow path 217 through the temperature-adjusting-medium pipe 218 by the temperature-adjusting-medium circulating mechanism 219. Thus, the temperature of the peripheral member 201 is controlled to a first temperature. In the meantime, the temperature adjusting medium is caused to flow into the temperature-adjusting-medium flow path 227 through the temperature-adjusting-medium pipe 228 by the temperature-adjusting-medium circulating mechanism 229. Thus, the temperature of the central member 202 is controlled to a second temperature differing from the temperature of the peripheral member 201.

The peripheral placing member 203 is formed into a ring shape in a corresponding relationship with the peripheral portion of the wafer W. The peripheral placing member 203 is, for example, detachably attached to the peripheral member 201. The peripheral placing member 203 includes a guide portion 203a which forms an outer edge and a placing portion 203b which exists inside the guide portion 203a. The guide portion 203a is formed to protrude upward and downward. The wafer W is guided by the upper portion of the guide portion 203a. A step portion 201a is formed at the outer edge of the peripheral member 201. The lower portion of the guide portion 203a is fitted to the step portion 201a, so as to determine a position of the guide portion 203a. The peripheral portion of the wafer W is placed on the placing portion 203b.

The central placing member 204 is in a specified positional relationship with the central member 202 and is, for example, detachably attached to the central member 202.

The peripheral placing member 203 and the central placing member 204 differ in shape from the peripheral member 201 and the central member 202 so as to correspond to the processing distribution. For example, as shown by a plan view in FIG. 9, the central placing member 204 has an elliptical shape. The peripheral placing member 203 has an annular shape corresponding to the central placing member 204. Therefore, when the peripheral placing member 203 and the central placing member 204 are mounted, a gap 261 is formed between the peripheral placing member 203 and the central placing member 204. Thus, the peripheral placing member 203 and the central placing member 204 are kept out of contact with each other. The peripheral placing member 203 and the central placing member 204 are not limited to this shape, but may have different shapes depending on the processing distribution.

Three projections 242 are formed on the surface of central placing member 204. A wafer W is placed on the projections 242.

Since the central placing member 204 differs in shape from the central member 202, an overhang portion 204a protruding from the central member 202 toward the peripheral member 201 exists at the central placing member 204 as shown in FIG. 10. A gap 262 is formed between the overhang portion 204a and the peripheral member 201. Therefore, when the chamber 40 is vacuum-exhausted, the overhang portion 204a is vacuum-insulated from the peripheral member 201. While not shown in the drawings, an overhang portion protruding toward the central member 202 exists at the peripheral placing member 203. A gap is formed between the overhang portion and the central member 202. Therefore, the overhang portion is vacuum-insulated from the central member 202. In the meantime, the region of the peripheral placing member 203 corresponding to the peripheral member 201 makes contact with the peripheral member 201. The region of the central placing member 204 corresponding to the central member 202 makes contact with the central member 202.

As a result, the front surface of the central placing member 204 including the overhang portion 204a is temperature-adjusted to a temperature substantially equal to the second temperature of the central member 202. This is due to the heat transfer from the central member 202 which is temperature-adjusted to the second temperature by the temperature adjusting medium. On the other hand, the front surface of the peripheral placing member 203 including the overhang portion (not shown) is temperature-adjusted to a temperature substantially equal to the first temperature of the peripheral member 201. This is due to the heat transfer from the peripheral member 201 which is temperature-adjusted to the first temperature by the temperature adjusting medium.

A wafer W as a workpiece substrate is supported by the projections 242 as mentioned above. A small gap is formed between the wafer W and the front surfaces of the peripheral placing member 203 and the central placing member 204. In this way, since the wafer W is placed with a small gap, the heat of the peripheral placing member 203 and the central placing member 204 is transferred to the wafer W via a gas introduced into the chamber 40. Thus, the region of the wafer W corresponding to the peripheral placing member 203 is temperature-adjusted to a temperature substantially equal to the first temperature. The region of the wafer W corresponding to the central placing member 204 is temperature-adjusted to a temperature substantially equal to the second temperature.

While not shown in the drawings, three through-holes are formed at each of the central member 202 and the central placing member 204. Lifter pins which can protrude and retract with respect to the front surface of the central placing member 204 and which can support and move up and down a wafer W are installed within the through-holes. The lifter pins are moved up and down by a cylinder not shown. When delivering the wafer W, the lifter pins are moved upward such that the tips of the lifter pins are positioned higher than the front surface of the central placing member 204.

The respective members of the substrate placing table 42′ are made of a metal superior in heat conductivity, e.g., aluminum. This makes it possible to efficiently transfer the heat of the temperature adjusting medium to the respective members and to accurately adjust the temperature of the wafer W as a substrate.

As described above, in the present embodiment, just like the first embodiment, the peripheral placing member 203 and the central placing member 204 corresponding to the processing distribution and differing in shape from the peripheral member 201 and the central member 202 are placed on the temperature-adjusted peripheral member 201 and the temperature-adjusted central member 202. The temperature of the front surface of the peripheral placing member 203 is set to become a temperature corresponding to the temperature of the peripheral member 201. The temperature of the front surface of the central placing member 204 is set to become a temperature corresponding to the temperature of the central member 202. This makes it possible to adjust the temperature distribution of the wafer W in conformity with the processing distribution and to realize optimal temperature distribution control which makes the processing distribution uniform depending on the processes.

If multiple sets of the peripheral placing member 203 and the central placing member 204 having an optimal shape on a process-by-process basis are prepared, it is possible to select and mount a set of the peripheral placing member 203 and the central placing member 204 suitable for the process to be implemented. Consequently, the temperature distribution control capable of making the processing distribution uniform can be executed by merely replacing the peripheral placing member 203 and the central placing member 204. This makes it possible to realize optimal temperature distribution control for the respective processes in a cost-effective manner.

In the COR processing apparatus 5′ of the present embodiment, the same COR process as that of the first embodiment is performed. After the COR process is finished, the gate valves 22 and 54 are opened. The processed wafer W on the substrate placing table 42′ is received by the pick of the second wafer transfer mechanism 17 and is transferred to the PHT processing apparatus. In the PHT processing apparatus, the reaction products generated by the COR process are heated, vaporized and removed.

As described above, according to the first and second embodiments, the peripheral placing member configured to support the peripheral portion of the wafer as a workpiece substrate and the central placing member configured to support the central portion of the wafer are installed on the peripheral member temperature-controlled to the first temperature and on the central member temperature-controlled to the second temperature. Thus, the peripheral placing member and the central placing member make contact with the peripheral member and the central member, but so as not to make contact with each other. The peripheral placing member and the central placing member are formed into shapes differing from the shapes of the peripheral member and the central member, respectively, so as to correspond to the processing distribution. The temperature of the front surface of the peripheral placing member is set to become a temperature corresponding to the temperature of the peripheral member. The temperature of the front surface of the central placing member is set to become a temperature corresponding to the temperature of the central member. This makes it possible to adjust the temperature distribution of the workpiece substrate in conformity with the processing distribution and to realize optimal temperature distribution control which makes the processing distribution uniform depending on the processes.

If multiple sets of the peripheral placing member and the central placing member are prepared in a corresponding relationship with a plurality of processes and if a set of the peripheral placing member and the central placing member suitable for the process to be implemented is selected and mounted, the temperature distribution control capable of making the processing distribution uniform can be executed by merely replacing the peripheral placing member and the central placing member. This makes it possible to realize optimal temperature distribution control for the respective processes in a cost-effective manner.

The present disclosure is not limited to the embodiments described above, but may be differently modified. For example, in the embodiments described above, the present disclosure is applied to the COR processing apparatus. However, the present disclosure is not limited thereto. The present disclosure may be applied to a process in which the processing distribution can be controlled by adjusting the temperature of a substrate placing table, e.g., a film-forming process performed by a chemical vapor deposition method (CVD method).

In the embodiments described above, the vacuum insulation is provided by forming a gap between the peripheral member and the central member and by forming gaps between the peripheral member and the overhang portion of the central placing member and between the central member and the overhang portion of the peripheral placing member. Instead of forming the gaps, insulation may be provided by interposing members having a heat insulation property.

In the embodiments described above, the temperatures of the peripheral member and the central member are controlled by allowing a temperature adjusting medium to flow through the temperature-adjusting-medium flow paths. However, the present disclosure is not limited thereto. The temperatures may be controlled by installing heaters at the peripheral member and the central member.

In the embodiments described above, there are examples where two workpiece substrates are processed at one time and one workpiece substrate is processed at one time. However, the present disclosure is not limited thereto, and three or more workpiece substrates may be processed at one time.

In the embodiments described above, description has been made using a semiconductor wafer as an example of the workpiece substrate. In view of the principle of the present disclosure, it is apparent that the workpiece substrate is not limited to a semiconductor wafer. Needless to say, the present disclosure can be applied to the processing of other different substrates.

### EXPLANATION OF REFERENCE NUMERALS

1: processing system, 2: carry-in/carry-out part, 3: load lock chamber, 4: PHT processing apparatus, 5, 5′: COR processing apparatus, 40: chamber, 42, 42′: substrate placing table, 43: gas supply mechanism, 44: exhaust mechanism, 54: gate valve, 83: automatic pressure control valve (APC), 90: control unit, 101, 201: peripheral member, 102, 202: central member, 103, 203: peripheral placing member, 104, 204: central placing member, 111: peripheral portion, 112: peripheral portion connecting portion, 113, 126, 151, 152, 213, 261, 262: gap, 117, 127, 217, 227: temperature-adjusting-medium flow path, 119, 129, 219, 229: temperature-adjusting-medium circulating mechanism, 121: central portion, 122: central portion connecting portion, 131: peripheral placing portion, 141: central placing portion, 141a and 204a: overhang portion, 142, 242: projections, W: semiconductor wafer (workpiece substrate)

What is claimed is:

1. A substrate placing table for supporting a workpiece substrate in a substrate processing apparatus which performs a specified process with respect to the workpiece substrate, comprising:
a peripheral member installed in a corresponding relationship with a peripheral portion of the workpiece substrate and temperature-controlled to a first temperature;
a central member installed in a corresponding relationship with a central portion of the workpiece substrate, the central member insulated from the peripheral member and temperature-controlled to a second temperature differing from the first temperature;
a peripheral placing member installed above the peripheral member so as to make contact with the peripheral member and configured to support the peripheral portion of the workpiece substrate; and
a central placing member installed above the central member so as to make contact with the central member and so as to be insulated from the peripheral placing member, the central placing member configured to support the central portion of the workpiece substrate,
wherein the peripheral placing member and the central placing member are formed into shapes differing from the shapes of the peripheral member and the central member, respectively, so as to correspond to a processing distribution,
the peripheral placing member is installed such that a portion of the peripheral placing member corresponding to the peripheral member makes contact with the peripheral member and a portion of the peripheral placing member protruding toward the central member is insulated from the central member, and
the central placing member is installed such that a portion of the central placing member corresponding to the central member makes contact with the central member and a portion of the central placing member protruding toward the peripheral member is insulated from the peripheral member.

2. The substrate placing table of claim 1, wherein the central member is kept out of contact with the peripheral member and insulated from the peripheral member by a gap formed between the central member and the peripheral member,
the central placing member is kept out of contact with the peripheral placing member and insulated from the peripheral placing member by a gap formed between the central placing member and the peripheral placing member,
the portion of the peripheral placing member protruding toward the central member is insulated from the central member by a gap formed between the portion of the peripheral placing member and the central member, and
the portion of the central placing member protruding toward the peripheral member is insulated from the peripheral member by a gap formed between the portion of the central placing member and the peripheral member.

3. The substrate placing table of claim 1, wherein the peripheral member includes an annular peripheral portion corresponding to the peripheral portion of the workpiece substrate,
the central member includes a disc-shaped central portion corresponding to the central portion of workpiece substrate,
the peripheral placing member includes a peripheral placing portion installed above the peripheral portion of the peripheral member, and
the central placing member includes a central placing portion installed above the central portion of the central member.

4. The substrate placing table of claim 1, wherein at least two workpiece substrates are placed on the substrate placing table,
the peripheral member includes at least two peripheral portions corresponding to peripheral portions of the respective workpiece substrates and a peripheral portion connecting portion configured to interconnect the peripheral portions,
the central member includes at least two central portions corresponding to central portions of the respective workpiece substrates and a central portion connecting portion configured to interconnect the central portions,
the peripheral placing member includes at least two peripheral placing portions installed above the peripheral portions, and
the central placing member includes at least two central placing portions installed above the central portions.

5. The substrate placing table of claim 4, wherein at least two said peripheral portions have an annular shape and at least two said central portions have a disc shape.

6. The substrate placing table of claim 1, wherein plural sets of the peripheral placing member and the central placing member are prepared in a corresponding relationship with a plurality of processes, and a set of the peripheral placing member and the central placing member suitable for a process to be implemented is selected and mounted.

7. The substrate placing table of claim 1, wherein the peripheral member and the central member include temperature-adjusting-medium flow paths installed therein, and further comprising: temperature-adjusting-medium circulating mechanisms configured to independently supply a temperature adjusting medium to the temperature-adjusting-medium flow paths, such that the temperature adjusting medium circulates through the temperature-adjusting-medium flow paths.

8. The substrate placing table of claim 1, wherein projections configured to support the workpiece substrate are formed on a front surface of the central placing member.

9. A substrate processing apparatus for implementing a specified process with respect to a workpiece substrate under a vacuum atmosphere, comprising:
a chamber configured to accommodate the workpiece substrate;
an exhaust mechanism configured to vacuum-exhaust the interior of the chamber;
a process gas introduction mechanism configured to introduce a process gas into the chamber; and
a substrate placing table configured to support the workpiece substrate within the chamber,
wherein the substrate placing table comprises:
a peripheral member installed in a corresponding relationship with a peripheral portion of the workpiece substrate and temperature-controlled to a first temperature;
a central member installed in a corresponding relationship with a central portion of the workpiece substrate, the central member insulated from the peripheral member and temperature-controlled to a second temperature differing from the first temperature;
a peripheral placing member installed above the peripheral member so as to make contact with the peripheral member and configured to support the peripheral portion of the workpiece substrate; and
a central placing member installed above the central member so as to make contact with the central member and so as to be insulated from the peripheral placing member, the central placing member configured to support the central portion of the workpiece substrate,
wherein the peripheral placing member and the central placing member are formed into shapes differing from the shapes of the peripheral member and the central member, respectively, so as to correspond to a processing distribution,
the peripheral placing member is installed such that a portion of the peripheral placing member corresponding to the peripheral member makes contact with the peripheral member and a portion of the peripheral placing member protruding toward the central member is insulated from the central member, and
the central placing member is installed such that a portion of the central placing member corresponding to the central member makes contact with the central member and a portion of the central placing member protruding toward the peripheral member is insulated from the peripheral member.
